(19) United States
(12) Patent Application Publication
(10) Pub. No.: US 2026/0051862 A1
(43) Pub. Date: Feb. 19, 2026

(54) AMPLIFIER SYSTEM WITH ENHANCED LOAD DRIVING CAPABILITY

(71) Applicant: ANALOG DEVICES, INC., Wilmington, MA (US)

(72) Inventors: Quan Wan, Wilmington, MA (US); Brian D. Hamilton, Wilmington, MA (US); Gregory Lawrence DiSanto, Wilmington, MA (US); Alec Julius Poitzsch, Wilmington, MA (US)

(73) Assignee: ANALOG DEVICES, INC., Wilmington, MA (US)

(21) Appl. No.: 18/804,318

(22) Filed: Aug. 14, 2024

(51) Int. Cl. H03F 3/24; H03F 1/30

(52) U.S. Cl. CPC H03F 3/245; H03F 1/30

(57) ABSTRACT

Embodiments of an amplifier system with enhanced load-driving capability are disclosed. The amplifier system comprises a main amplifier and multiple parallel output stages. Each additional output stage receives a current signal proportional to the main amplifier output current and outputs the replica of the main amplifier output current. An amplifier control circuit in the main amplifier receives current signals representing the current of each additional output stage to set a quiescent current of the amplifier system accordingly to ensure stability while minimizing quiescent power dissipation. Advantages of the amplifier system embodiments include unlimited load driving capability in principle, greatly relieved burden on thermal management, cost-effectiveness, design flexibility over single chip solutions, controllable current biasing of each output stage attached to the system, and controllable quiescent power dissipation based on application.

### BACKGROUND

### A. Technical Field

The present disclosure relates generally to amplifier systems. More particularly, the present disclosure relates to amplifier systems with enhanced load-driving capability.

### B. Background

An amplifier is an electronic device that uses electric power from a power supply to amplify the magnitude of a time-varying voltage or current signal. Amplifiers are widely used in almost all electronic equipment. It is desirable that amplifiers have large load-driving capability while having a low quiescent power dissipation.

Multiple amplifiers may be combined to increase load-driving capability. FIG. 1 depicts scenarios with two amplifiers placed in parallel to double current driving capability. As shown in configuration (A) on the left side of FIG. 1, two amplifiers are placed in parallel to double the current driving capability. However, these two amplifiers usually have different offset voltages; thus, resistors are needed to isolate the two amplifiers at their output nodes. A compromise must be made between voltage drop (headroom) and circulating current on the resistors. As shown in configuration (B) on the right side of FIG. 1, two amplifiers are placed in parallel with the output nodes of the first stage brought to external pins and tied together, thus, isolation resistors are not needed in this scheme. However, in both cases, the quiescent power dissipation is doubled. In addition, it is not cost-effective because, to deliver extra current, essentially, we only need additional output devices rather than additional amplifiers

Accordingly, what is needed are systems and methods to enhance the load-driving capability of an amplifier system without limiting the bandwidth and slew-rate of the output signal.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not to scale.

FIG. 1 depicts scenarios with two amplifiers placed in parallel to double current driving capability.

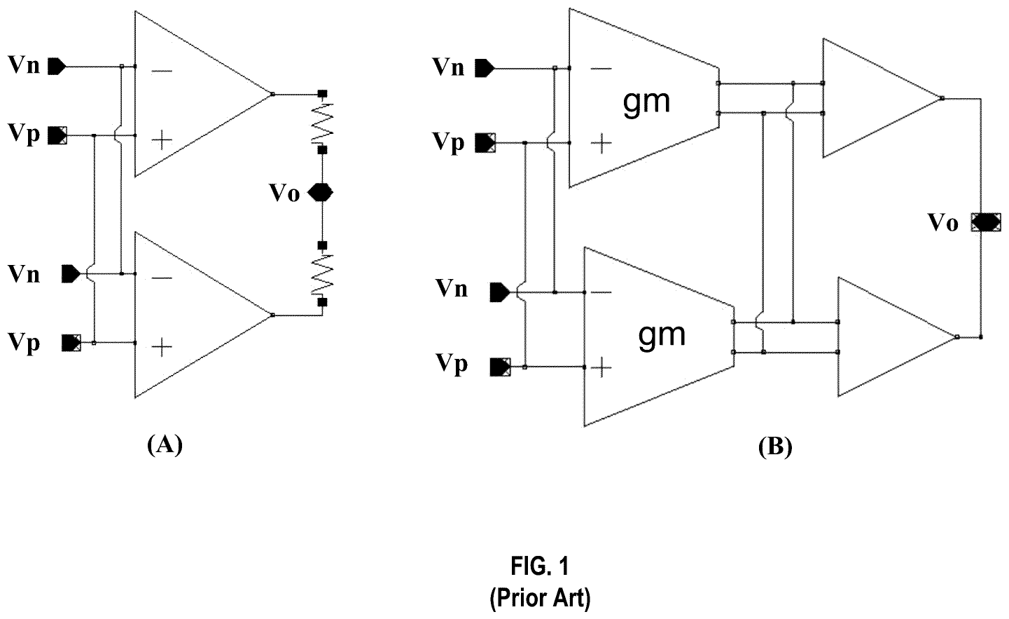

FIG. 2 depicts an amplifier system with enhanced load-driving capability in accordance with various embodiments of the invention.

FIG. 3 depicts an amplifier system with enhanced load-driving capability and two rail-to-rail output stages in accordance with various embodiments of the invention.

FIG. 4 depicts an amplifier system with enhanced load-driving capability and a variant of output stages in accordance with various embodiments of the invention.

FIG. 5 depicts an amplifier system with multiple output stages in daisy chain in accordance with various embodiments of the invention.

FIG. 6 depicts a process of enhancing load-driving capability for an amplifier system in accordance with various embodiments of the invention.

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion that components may be described as separate functional units, which may comprise sub-units, but those skilled in the art will recognize that various components, or portions thereof, may be divided into separate components or may be integrated together, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgement, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification are not necessarily all referring to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

One skilled in the art shall recognize that: (1) certain steps may optionally be performed; (2) steps may not be limited to the specific order set forth herein; (3) certain steps may be performed in different orders; and (4) certain steps may be done concurrently.

Any headings used herein are for organizational purposes only and shall not be used to limit the scope of the description or the claims. Each reference/document mentioned in this patent document is incorporated by reference herein in its entirety.

In this document, the term “amplifier” is defined as an electronic device that uses electric power from a power supply to amplify the magnitude of a time-varying voltage or current signal. Amplifiers may be classified into different amplifier types according to the amplifier's characteristics and performance. A class A amplifier is an amplifier that conducts current through the period of an input signal. A class B amplifier is an amplifier that conducts current only for one-half period of an input signal. A Class AB amplifier is an amplifier that combines Class A and Class B to achieve an amplifier with more efficiency than Class A but with lower distortion than Class B. The term “quiescent current” is defined as the current level in an amplifier when it generates a zero output. A daisy chain is a wiring scheme in which multiple devices are wired together in sequence or in a ring, similar to a garland of daisy flowers.

Described hereinafter are system and method embodiments to enhance amplifier load-driving capability. The implementation of these embodiments may achieve enhanced load-driving capability in a flexible and cost-effective configuration without increasing total quiescent power dissipation.

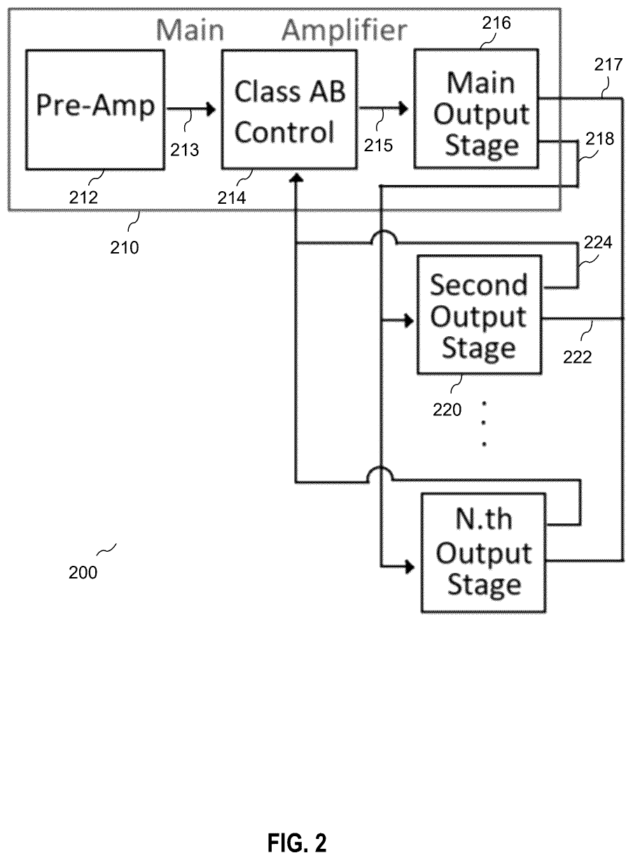

FIG. 2 depicts an amplifier system with enhanced load-driving capability in accordance with various embodiments of the invention. The amplifier system 200 comprises a main amplifier 210 and one or more additional output stages 220. The main amplifier 210 comprises a preamplifier 212, an amplifier control circuit 214, and a main output stage (also referred to as a first output stage) 216. The one or more additional output stages 220 are configured in parallel, with each additional output stage receiving a current signal 218 proportional to the main amplifier output current 217 and outputting an additional output current 222 that is a replica of the main amplifier output current 218. In one or more embodiments, the main amplifier and each additional output stage may be fabricated on individual silicon, assembled in individual packages separately, and connected discretely.

The amplifier control circuit 214 receives a preamplified signal 213 from the preamplifier 212 and a feedback current signal 224 from additional output stages 220 to generate a drive signal 215 to drive the main output stage 216. The feedback current signal 224 represents the additional output current 222 of each additional output stage 220. In one or more embodiments, the amplifier control circuit 214 is a class AB controller that controls one or more operational parameters of the main amplifier 210. In one or more embodiments, the amplifier control circuit 214 may set a quiescent current of the amplifier system 200 based at least on the feedback current signal 224 from each additional output stage 220 to ensure stability while minimizing quiescent power dissipation.

It is neither cost-effective nor technically feasible to make one amplifier to cover all applications to accommodate a variety of applications. For example, in some applications, only an amplifier is needed to deliver hundreds of milliamps. While in other applications, an amplifier is needed to deliver tens amp current. If a single-chip solution is used to cover all applications, the amplifier needs to be designed for a worst-case scenario, and the output stage would be enormous and unnecessarily large for other applications. In addition, assuming the amplifier is powered with +−100V and delivers a 10 A current, the power dissipation would be 1 KW. Thermal management on the package for such a power dissipation would be extremely challenging.

With the amplifier system shown in FIG. 2, assuming each output stage delivers 1 A current, nine additional output stages may be attached to the main amplifier to deliver 10 A current. In this configuration, the power dissipation for each chip is limited to 100 Watts, thus greatly relieving the challenge of thermal management. Each output stage is only sized for 1 A maximum current, thus keeping the silicon area small. Furthermore, the amplifier system 200 may be configured adaptively. In another example, if only 2 A current is needed, only one additional output stage needs to be attached to the main amplifier. In principle, the amplifier system 200 provides unlimited current driving capacity since many output stages may be attached in parallel as needed.

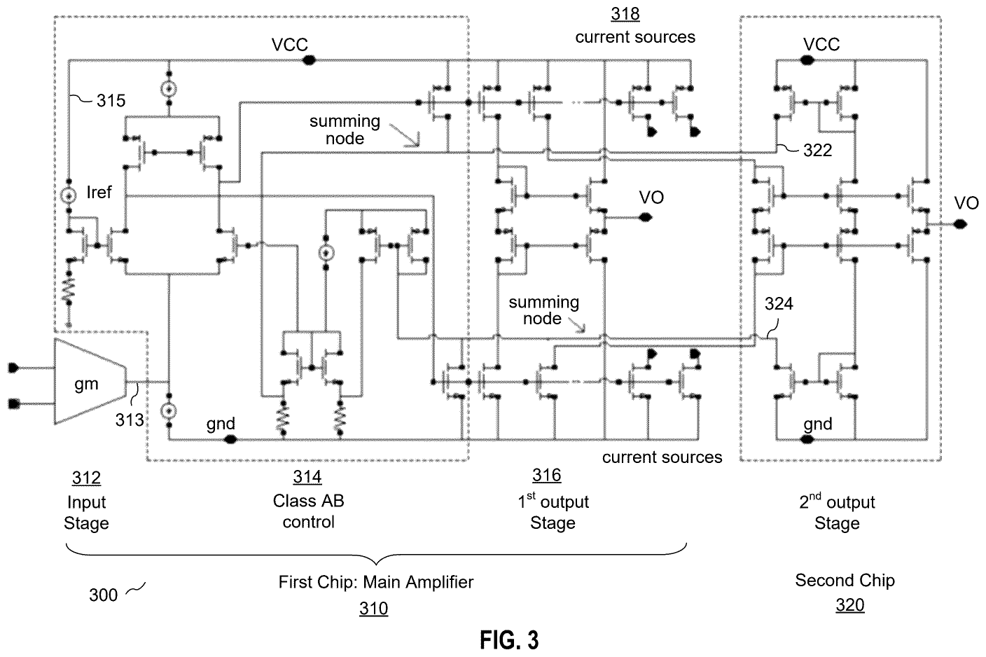

FIG. 3 depicts an amplifier system with enhanced load-driving capability and two rail-to-rail output stages in accordance with various embodiments of the invention. System 300 comprises two components, each component packaged in its own chip. The first component is a main amplifier 310 comprising an input stage (a preamplifier) 312, an amplifier control circuit (e.g., a class AB control loop) 314, a first output stage 316, and multiple current sources 318. The second component is an additional output stage 320 in parallel to the first output stage 316. For simplicity, only one additional output stage is attached to the main amplifier in FIG. 3, although more additional output stages may be attached in parallel to the main amplifier.

The input stage 312 may be an operational transconductance amplifier (OTA) that converts a differential input voltage (Vp−Vn) to an input current 313 for further amplification. The multiple current sources 318 are configured in a multiple-pair layout, with each current source pair driving one output stage (the first output stage 316, the second output stage 320, etc.).

A pair of feedback signals 322/324 of each additional output stage current are respectively brought back to a pair of summing nodes in the amplifier control circuit 314. The feedback loop in the class AB control circuit sets a total quiescent current of all output stages (e.g., a sum of the 1^{st} and 2^{nd} output stages) proportional to a reference current Iref 315. Thus, after the 2^{nd} output stage is attached to the main amplifier, the quiescent current of the 1^{st} output stage can be scaled down accordingly. In this manner, the amplifier system may deliver twice as much load current as the main amplifier while the total quiescent current stays the same.

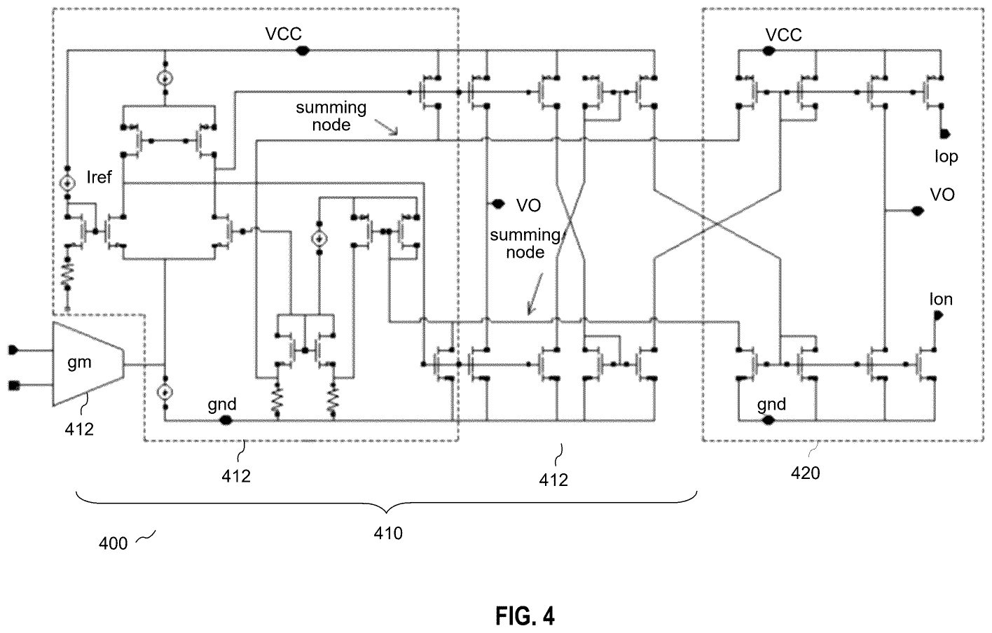

FIG. 4 depicts an amplifier system with enhanced load-driving capability and a variant of output stages in accordance with various embodiments of the invention. The amplifier system 400, mainly similar to the amplifier system 300 disclosed in FIG. 3, comprises a main amplifier 410 and an additional output stage 420. The main amplifier 410 comprises an input stage 412, an amplifier control circuit (e.g., a class AB control loop) 414, a first output stage 416, and multiple current sources 418.

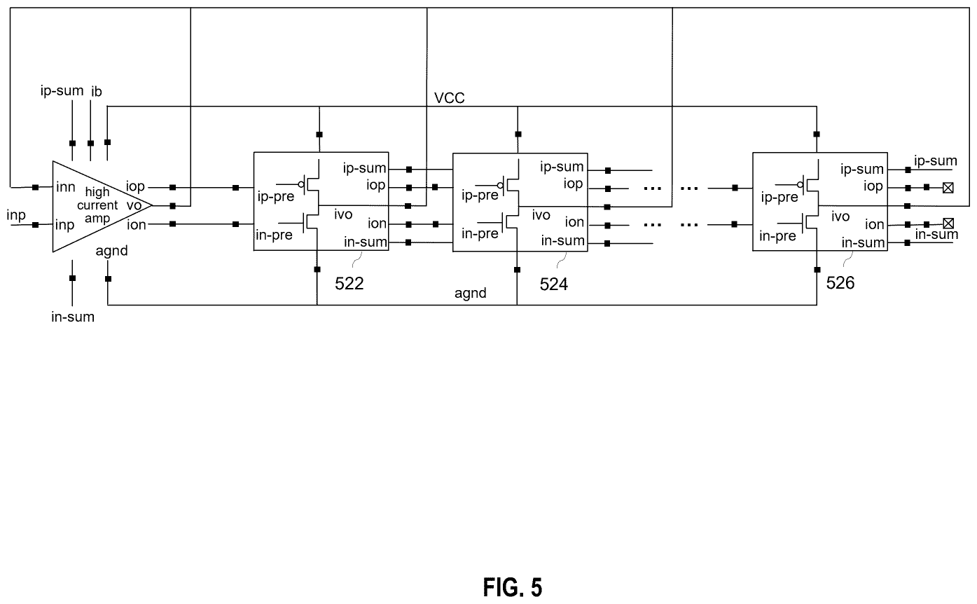

Different from the output stage disclosed in FIG. 3, the output stage in FIG. 4 may have two additional pins Iop and Ion to send out current signals proportional to its output current. With this arrangement, multiple output stages 522, 524, and 526 can be connected in a daisy chain, as shown in FIG. 5. The advantage of this arrangement is that fewer pins need to be added to the main amplifier, although additional delay may degrade the amplifier system transient response.

Advantages of the amplifier system embodiments in the present invention include but are not limited to unlimited load driving capability in principle, greatly relieved burden on thermal management, flexible and cost-effective, controllable total quiescent power dissipation based on applications after additional output stages attached to the system, individually controllable output current for each output stage current.

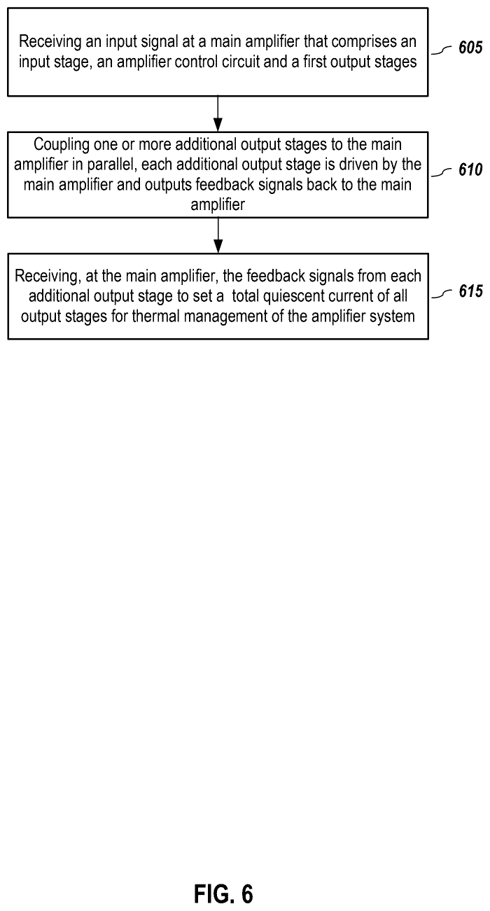

FIG. 6 depicts a process of enhancing load-driving capability for an amplifier system in accordance with various embodiments of the invention. The process begins at step 605, in which an input signal is received at a main amplifier that comprises an input stage, an amplifier control circuit, and a first output stage.

In step 610, one or more additional output stages are coupled in parallel to the main amplifier. Each additional output stage is driven by the main amplifier and outputs feedback signals that are fed back to the main amplifier.

In step 615, the main amplifier receives the feedback signals from each additional output stage to set a total quiescent current of all output stages for thermal management of the amplifier system.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently, including having multiple dependencies, configurations, and combinations.

What is claimed is:

1. An amplifier system comprising:
a main amplifier comprising:
a preamplifier that receives an input signal to generate a preamplified signal;
an amplifier control circuit that receives the preamplified signal to generate a drive signal; and
a first output stage that receives the drive signal to generate a main amplifier output current; and
one or more additional output stages coupled to the main amplifier in parallel, each additional output stage receives from the main amplifier a current signal proportional to the main amplifier output current and outputs an additional output current.

2. The amplifier system of claim 1, wherein the main amplifier and each additional output stage are fabricated in individual chips.

3. The amplifier system of claim 1, wherein the main amplifier and each additional output stage are packaged separately and connected discretely.

4. The amplifier system of claim 1, wherein the amplifier control circuit receives a pair of feedback current signals from each additional output stage to set a total quiescent current of all output stages.

5. The amplifier system of claim 4, wherein the total quiescent current of all output stages is proportional to a reference current.

6. The amplifier system of claim 4, wherein the pair of feedback current signals from each additional output stage are respectively brought back to a pair of summing nodes in the amplifier control circuit.

7. The amplifier system of claim 1, wherein each additional output stage has two pins to send out current signals proportional to its output current.

8. The amplifier system of claim 7, wherein the one or more additional output stages are connected in a daisy chain using the two pins of each additional output stage.

9. The amplifier system of claim 1, wherein the input signal is a differential input voltage, the preamplifier is an operational transconductance amplifier (OTA) that converts the differential input voltage into an input current.

10. The amplifier system of claim 1 further compirsing:
multiple current sources that are configured in a multiple-pair layout with each current source pair driving one output stage.

11. A method of enhancing load driving capability, the method comprising:
reciving an input signal at a main amplifier, the main amplifier that comprises an input stage, an amplifier control circuit, and a first output stage;
coupling one or more additional output stages to the main amplifier in parallel, each additional output stage is driven by the main amplifier and outputs a pair of feedback signals back to the main amplifier; and
receiving, at the main amplifier, the pair of feedback signals from each additional output stage to set a total quiescent current of all output stages for thermal management of the amplifier system.

12. The method of claim 11, wherein the main amplifier and each additional output stage are separate chips.

13. The method of claim 11, wherein the main amplifier and each additional output stage are packaged separately and connected discretely.

14. The method of claim 11, wherein the number of additional output stages are adaptively determined by applications of the main amplifier.

15. The method of claim 11, wherein the total quiescent current of all output stages is proportional to a reference current.

16. The method of claim 11, wherein the pair of feedback current signals from each additional output stage are brought back respectively to a pair of summing nodes in the amplifier control circuit.

17. The method of claim 11, wherein each additional output stage has two pins to send out current signals proportional to its output current.

18. The method of claim 17, wherein the one or more additional output stages are connected in a daisy chain using the two pins of each additional output stage.

19. The method of claim 11, wherein the input signal is a differential input voltage, the preamplifier is an operational transconductance amplifier (OTA) that converts the differential input voltage into an input current.

20. The method of claim 11, wherein the main amplifier further comprises multiple current sources configured in a multiple-pair layout with each current source pair driving one additional output stage.
